(19) United States
(12) Patent Application Publication
(10) Pub. No.: US 2019/0035996 A1
(43) Pub. Date: Jan. 31, 2019

(54) THERMOELECTRIC MATERIAL INK, THERMOELECTRIC ELEMENT AND THERMOELECTRIC DEVICE MANUFACTURED USING THE THERMOELECTRIC MATERIAL INK, AND METHOD OF MANUFACTURING THE THERMOELECTRIC DEVICE

(71) Applicants: Samsung Electronics Co., Ltd., Suwon-si (KR); THE REGENTS OF THE UNIVERSITY OF CALIFORNIA, A CALIFORNIA CORPORATION, Oakland, CA (US)

(72) Inventors: Renkun CHEN, San Diego, CA (US); Joseph WANG, San Diego, CA (US); Sunmi SHIN, San Diego, CA (US); Rajan KUMAR, La Jolla, CA (US); Jongwook ROH, Anyang-si (KR)

(21) Appl. No.: 16/048,686

(22) Filed: Jul. 30, 2018

Related U.S. Application Data
(60) Provisional application No. 62/539,108, filed on Jul. 31, 2017.

(30) Foreign Application Priority Data
Jun. 22, 2018 (KR) 10-2018-0072225

(51) Int. Cl. H01L 35/26; H01L 35/32; H01L 35/34; C09D 11/52; C09D 11/08; C09D 11/037

(52) U.S. Cl. CPC H01L 35/26; H01L 35/32; C09D 11/037; C09D 11/52; C09D 11/08; H01L 35/34

(57) ABSTRACT

A thermoelectric material ink including a binder with a cellulosic ether, a thermoelectric element, and a thermoelectric device that are manufactured using the thermoelectric material ink, and a method of manufacturing the thermoelectric device are provided. A printed thermoelectric device having high thermoelectric performance may be manufactured using the thermoelectric material ink.

### CROSS-REFERENCE TO RELATED APPLICATION

This application claims the benefit of U.S. Patent Application No. 62/539,108, filed on Jul. 31, 2017 in the United States Patent and Trademark Office, and Korean Patent Application No. 10-2018-0072225, filed on Jun. 22, 2018, in the Korean Intellectual Property Office, the disclosures of which are incorporated herein in their entirety by reference.

This invention was made with government support under grant DE-AR0000535 awarded by the Department of Energy. The government has certain rights in the invention.

### BACKGROUND

### 1. Field

The present disclosure relates to a thermoelectric material ink, a thermoelectric element, and a thermoelectric device that are manufactured using the thermoelectric material ink, and a method of manufacturing the thermoelectric device.

### 2. Description of the Related Art

A thermoelectric phenomenon is a reversible, direct energy conversion from heat to electricity and vice versa, which occurs due to movements of electrons and/or holes in a thermoelectric material.

Examples of the thermoelectric phenomenon include the Peltier effect, in which two dissimilar materials are connected at a contact point where heat is released or absorbed due to a current applied from the outside; the Seebeck effect, in which an electromotive force is generated due to a temperature difference between the ends of the dissimilar materials that are connected at the contact point; and the Thomson effect, in which heat is released or absorbed as a current is applied to a material having a predetermined temperature gradient.

Thermoelectric materials are currently being used in an active cooling system for semiconductor equipment and electronic devices that experience heat problems when passive cooling systems are used. In addition, the demand for such thermoelectric materials is also increasing in fields where heat problems are unsolvable using conventional refrigerant gas compression systems such as precision temperature control systems applied for DNA research. Thermoelectric cooling is a non-vibration, low-noise, environment-friendly cooling technology that does not use refrigerant gases causing environmental problems. If cooling efficiency is improved through development of highly-efficient thermoelectric cooling materials, it may be possible to expand the application field of the thermoelectric cooling materials to the field of general-purpose cooling such as refrigerators, air conditioners, and the like. When thermoelectric materials are applied to heat emission parts such as a car engine or a heat emission region of an industrial plant, it may be possible to generate electric power due to a temperature difference at the ends of the thermoelectric materials. In this respect, thermoelectric materials are drawing attention as new and renewable energy sources, and such thermoelectric power generation systems are already in operation in space probes for exploration of planets such as Mars and Saturn. Such thermoelectric generation systems may also be applicable as a power source of flexible devices, in particular, flexible wearable devices in the future.

In general, a thermoelectric module of the related art is manufactured using a solid-phase synthesis method by ingot manufacturing and dicing, wherein solder is used to connect the thermoelectric material and an electrode. However, this method has constraints such as the need for a hard solid substrate. This constraint may block application of thermoelectric elements to flexible devices, in particular, flexible devices that are wearable. In addition, the method of the related art has drawbacks such as a difficulty of application to mass production and difficulties in process application.

Despite an increasing demand for printed thermoelectric devices, printed thermoelectric devices still have problems such as low thermoelectric performance.

Therefore, there is a need for development of thermoelectric material ink that may ensure high thermoelectric performance of a printed thermoelectric device.

### SUMMARY

Provided is a printable thermoelectric material ink that may exhibit improved thermoelectric performance.

Provided is a thermoelectric element manufactured using the thermoelectric material ink.

Provided is a thermoelectric module including the thermoelectric element.

Provided is a flexible thermoelectric device manufactured using the thermoelectric material ink.

Provided is a method of manufacturing the thermoelectric device.

Additional aspects will be set forth in part in the description which follows and, in part, will be apparent from the description, or may be learned by practice of the presented embodiments.

According to an aspect of an embodiment, a thermoelectric material ink includes: a thermoelectric semiconductor particle; a binder including a cellulose ether; and a solvent, wherein the thermoelectric material ink is screen-printable.

According to an embodiment, there is provided a thermoelectric element obtained by printing and sintering the above-described thermoelectric material ink and then hot pressing a resulting product, wherein an amount of carbon in the thermoelectric element is about 3 atom % or less.

According to an embodiment, a thermoelectric module includes: a first electrode; a second electrode; and the above-described thermoelectric element located between the first electrode and the second electrode.

According to an embodiment, a flexible thermoelectric device includes: a flexible substrate including a fabric; and a thermoelectric layer that is printed on the flexible substrate, wherein an amount of carbon in the thermoelectric layer is about 3 atom % or less.

According to an embodiment, a method of manufacturing a thermoelectric device includes: forming a thermoelectric layer on a flexible substrate including a fabric by screen-printing the above-described thermoelectric material ink; sintering the thermoelectric layer; and hot pressing the thermoelectric layer.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic conceptual view illustrating a process of manufacturing a thermoelectric element using a thermoelectric material ink, according to an embodiment;

FIGS. 2A and 2B are scanning electron microscope (SEM) images of microparticles and nanoparticles obtained in Example 1; FIG. 2C is an optical microscope image of a thermoelectric (TE) layer of Example 1 on a fabric substrate before hot pressing, and FIG. 2D is a Keyence 3D optical microscope image of the TE layer;

FIG. 3 is a graph of voltage (volts (V)) versus temperature difference (degree Kelvin (K)) illustrating in-plane Seebeck coefficient (S) measurement results of the TE layer of Example 1;

FIG. 4A illustrates an embodiment in which a TE layer was printed directly on a fabric substrate, and FIG. 4B illustrates an embodiment in which a TE layer was printed after formation of a chitosan layer on the fabric substrate;

FIGS. 4C and 4D are graphs of height (micrometers (μm)) versus x-coordinate (μm) illustrating results of surface roughness of fabric substrates used in Examples 1 and 2, respectively, observed using a Keyence optical surface profiler; FIGS. 4E and 4F are cross-sectional SEM images of the TE layer of Example 1 when the thickness of the TE layer was varied; and FIGS. 4G and 4H are graphs of electrical conductivity (siemens/centimeter (S/cm)) versus thickness (μm) illustrating electrical conductivity measurement results of the TE layers of Examples 1 and 2, respectively;

FIG. 5A is a schematic view of a setup used for a thermal conductivity measurement according to the Angstrom method; FIGS. 5B and 5C are graphs of temperature variance (K) versus time (seconds (s)) showing temperature wave measurement results of p-type BST and n-type BTS TE layers according to Example 1, respectively; and FIGS. 5D and 5E are plots of 3 ω voltage (V) and temperature increase (K) as a function of heating frequency (hertz (Hz)) in the p-type BST and n-type BTS TE layers, respectively, according to Example 1;

FIG. 6 are cross-sectional high resolution-transmission electron microscopy (HR-TEM) energy-dispersive X-ray spectroscopy (EDS) element mapping images of the n-type TE layer of Example 1;

FIGS. 7A and 7B are high-angle annular dark-field (HAADF) images of the p-type and n-type TE layers, respectively, of Example 1;

FIG. 8 is a schematic view of a thermoelectric module according to an embodiment;

FIG. 9 is a schematic view of a thermoelectric cooler according to an embodiment;

FIG. 10 is a schematic view of a thermoelectric generator according to an embodiment; and

FIGS. 11A to 11H are images showing printing results with TE inks of Comparative Examples 1 to 5 and Examples 3 to 5, respectively.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” and “upper,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of a thermoelectric material ink, a thermoelectric element and a thermoelectric device that are manufactured using the thermoelectric material ink, and a method of manufacturing the thermoelectric device will be described in greater detail.

For the application of a thermoelectric element to flexible devices, in particular, flexible wearable devices, there is an increasing demand for printable thermoelectric elements. However, low thermoelectric performance of printed thermoelectric materials is still problematic. A main cause of the low thermoelectric performance is due to the need of an organic additive such as a binder in preparing a thermoelectric material slurry having an appropriate viscosity. When the organic additive is not effectively removed after being used in a large amount, a resulting thermoelectric film may have a low electric conductivity and its use may be limited.

In this regard, to improve thermoelectric performance, the present inventors developed a thermoelectric material ink including a minimum amount of a binder, wherein the binder may be removed during sintering without oxidation of the thermoelectric material. In accordance with an embodiment, a thermoelectric material ink includes: a thermoelectric semiconductor particle; a binder including a cellulose ether; and a solvent. The thermoelectric material ink is screen-printable.

In pyrolysis, which is one of the methods for removing an organic binder from a thermoelectric material slurry, i.e., decomposition of organic species through combustion, a sufficient amount of oxygen is necessary at elevated temperatures. However, when the thermoelectric material slurry is exposed to oxygen, the thermoelectric material may be oxidized, which may affect thermoelectric characteristics. In contrast, the thermoelectric material ink according to one or more embodiments disclosed herein may use an amount of a binder that is significantly less, or a as small as possible, and thus may maintain a suitable viscosity for printability, and may allow greater, or even complete removal of the binder without oxidation of the components of the thermoelectric material.

In the thermoelectric material ink, the thermoelectric semiconductor particle may include any compound available in the art. For example, the thermoelectric semiconductor particle may include at least one thermoelectric semiconductor including at least one of a transition metal, a rare earth element, a Group 13 element, a Group 14 element, a Group 15 element, or a Group 16 element. The rare earth element may be Y, Ce, or La, the transition metal may be at least one of Ti, Zr, Hf, V, Nb, Ta, Cr, Mo, W, Mn, Fe, Co, Ni, Cu, Zn, Ag, or Re, the Group 13 element may be at least one of B, Al, Ga, or In, the Group 14 element may be at least one of C, Si, Ge, Sn, or Pb, the Group 15 element may be at least one of P, As, Sb, or Bi, and the Group 16 element may be at least one of S, Se, or Te. For example, at least one thermoelectric semiconductor including at least two of the above-listed elements may be used.

Examples of the thermoelectric semiconductor including the above-listed elements include a Bi—Te-based thermoelectric semiconductor, a Co—Sb-based thermoelectric semiconductor, a Pb—Te-based thermoelectric semiconductor, a Ge—Tb-based thermoelectric semiconductor, a Si—Ge-based thermoelectric semiconductor, a Sb—Te-based thermoelectric semiconductor, a Sm—Co-based thermoelectric semiconductor, and a transition metal silicide-based thermoelectric semiconductor. Electrical characteristics of the thermoelectric semiconductors may be improved by including, as a dopant, a transition metal, a rare earth element, a Group 13 element, a Group 14 element, a Group 15 element, or a Group 16 element as listed above.

The Bi—Te-based thermoelectric semiconductor may be, for example, a (Bi,Sb)₂(Te,Se)₃-based thermoelectric semiconductor using Sb and Se as dopants. The Co—Sb-based thermoelectric semiconductor may be, for example, a CoSb₃-based thermoelectric semiconductor. The Sb—Te-based thermoelectric semiconductor may be, for example, AgSbTe₂ or CuSbTe₂. The Pb—Te-based thermoelectric semiconductor may be, for example, PbTe, or (PbTe)ₘAgSbTe₂. In some embodiments, a Bi—Te-based thermoelectric semiconductor may be used due to its excellent thermoelectric performance at near room temperature.

The thermoelectric semiconductor may be of a p-type or an n-type depending on a compound composition.

The thermoelectric semiconductor may be prepared by using any of a variety of methods, for example, using any of the following methods. However, embodiments are not limited thereto:

a method using an ampoule, which includes putting a source material into a quartz pipe or a metal ampoule, which are then vacuum-sealed and then thermally treated;

an arc melting method, which includes putting a source material into a chamber and melting the source material by arc discharging under an inert gas atmosphere to thereby prepare a sample;

a solid state reaction method, which includes thoroughly mixing powder and hardening and thermally treating the powder mixture, or which includes thermally treating mixed powder and then processing and sintering a thermally treated product;

a metal flux method, which includes putting a source material and an element into a crucible, the element creating an atmosphere for satisfactory growing of the source material into crystals at a high temperature, and thermally treating the source material and the element at a high temperature to grow crystals;

a Bridgeman method, which includes putting a source material into a crucible, heating an end of the crucible at a high temperature until the source material in a high-temperature domain is dissolved, and slowly moving the high-temperature domain to locally dissolve the source material until all of the source material passes through the high-temperature domain to thereby grow crystals;

a zone melting method, which includes preparing a seed rod and a feed rod from a source material, and growing crystals by locally heating the seed rod and the feed rod at a high temperature to dissolve a sample while slowly moving a dissolved portion of the sample upwards;

a vapour transport method, which includes putting a source material in a lower portion of a quartz pipe, and heating the lower portion of the quartz pipe where the source material is while an upper portion of the quartz pipe is maintained at a low temperature, so that a solid state reaction occurs at the low temperature while the source material is vaporized, thereby growing crystals; and

a mechanical alloying method, which includes putting a source material powder and steel balls into a jar made of sintered carbide and rotating the jar, wherein the source material powder is alloyed by mechanical impact of the steel balls.

After the thermoelectric semiconductor is prepared using any of the above-described methods, the thermoelectric semiconductor may be separated according to average diameters for different uses by using a mechanical sieving method.

In some embodiments, the thermoelectric semiconductor particle may be obtained by effective destruction of a bulk thermoelectric semiconductor ingot into microparticles and nanoparticles by using a spark erosion process.

The thermoelectric semiconductor particle may include particles having a predetermined size, for example, having an average particle diameter of about 0.01 micrometer (μm) to about 100 μm.

In some embodiments, the thermoelectric semiconductor particle may have a bimodal particle size distribution including microparticles and nanoparticles. The microparticles may have an average particle diameter of about 1 μm to about 100 μm, and the nanoparticles may have an average particle diameter of about 10 nanometers (nm) to about 500 nm. For example, the microparticles may have an average particle diameter of about 1 μm to about 10 μm, and in some embodiments, about 10 μm to about 50 μm, and in some other embodiments, about 50 μm to about 100 μm. For example, the nanoparticles may have an average particle diameter of about 10 nm to about 50 nm, and in some embodiments, about 50 nm to about 100 nm, and in some other embodiments, about 100 nm to about 500 nm, and in some still other embodiments, about 300 nm to about 500 nm. The bimodal system may be obtained by grinding a bulk thermoelectric semiconductor ingot into a mixture of microparticles and nanoparticles in a size range as described above, or by mixing microparticles and nanoparticles that are previously separated by a size range as described above. In the thermoelectric semiconductor particle having a bimodal particle size distribution within any of the above-described ranges, empty spaces between the microparticles may be filled by the nanoparticles, so that the thermoelectric semiconductor particles may be closely compacted with a reduced pore space therebetween and thus may increase electrical conductivity of a thermoelectric element.

The thermoelectric material ink may further include a nanostructure, in addition to the thermoelectric semiconductor particle. For example, the nanostructure may include at least one 1-dimensional (1D) and/or 2-dimensional (2D) nanostructure such as a nanoplate, a nanodisk, a nanosheet, a nanowire, a nanofiber, a nanobelt, a nanotube, a nanocrystal, nanopowder, and a combination thereof. When introduced into the interface of the thermoelectric semiconductor particles in a thermoelectric element, these nanostructures may effectively scatter phonons, thus increasing a Seebeck coefficient and reducing thermal conductivity of the thermoelectric element.

The thermoelectric semiconductor particle may be mixed with the binder including a cellulose ether, and a solvent to form the thermoelectric material ink.

The binder may include a cellulose ether. The cellulose ether may maintain a suitable viscosity for printability of the thermoelectric material ink even at a minimum amount thereof, and may have a decomposition temperature that is lower than a temperature of common hot pressing and consequently be removed as much as possible by thermal decomposition at a relatively low temperature during sintering of the printed thermoelectric material ink without oxidization of the thermoelectric semiconductor particle.

The cellulose ether has a cellulose skeleton having D-glucopyranose repeating units linked to each other by β-1,4-glycosidic bonds, designated as anhydroglucose units. The cellulose ether may be, for example, alkyl cellulose, hydroxyalkyl cellulose, alkyl hydroxyalkyl cellulose, or a combination thereof. In the cellulose ether, hydroxyl groups of the anhydroglucose units may be partially substituted. The hydroxyl groups may be directly attached to a ring carbon atom of the cellulose skeleton, or to an alkyl group pendant to the ring, e.g., a methylene group. The hydroxyl groups may be partially substituted with an alkyl group to form an alkoxy group or a hydroxyalkyl group to form a hydroxyalkoxy group, or the cellulose ether may have a combination of an alkoxy group and a hydroxyalkoxy group. The alkoxy group may be, for example, a methoxy group, an ethoxy group, a propoxy group, or a combination thereof. For example, the alkoxy group may be a methoxy group. The hydroxyalkoxy group may be, for example, a hydroxymethoxy group, a hydroxyethoxy group, a hydroxypropoxy group, or a combination thereof. For example, the hydroxyalkoxy group may be a hydroxyethoxy group and/or a hydroxypropoxy group. The cellulose ether may include one or two hydroxyalkoxy groups.

Examples of the cellulose ether may be an alkyl cellulose, such as methyl cellulose, ethyl cellulose, or propyl cellulose; a hydroxyalkyl cellulose, such as hydroxyethyl cellulose, hydroxypropyl cellulose, and hydroxybutyl cellulose; a hydroxyalkyl alkyl cellulose (i.e., a cellulose containing hydroxyl groups substituted by both hydroxyalkyl groups and alkyl groups), such as hydroxyethyl methyl cellulose, hydroxymethyl ethyl cellulose, hydroxyethyl ethyl cellulose, hydroxypropyl methyl cellulose, hydroxypropyl ethyl cellulose, hydroxybutyl methyl cellulose, and hydroxybutyl ethyl cellulose; and those having two or more hydroxyalkyl groups or two or more hydroxyalkyl groups and an alkyl group, such as hydroxyethyl hydroxypropyl methyl cellulose. For example, the cellulose ether may be an alkyl cellulose, for example, methyl cellulose. The alkyl cellulose may have a low decomposition temperature and may impart an appropriate viscosity to the thermoelectric material ink even at a small amount thereof. In some embodiments a combination of different cellulose ethers may be used.

The average number of hydroxy groups substituted by alkyl or hydroxyalkyl groups, such as methoxy or hydroxyethyloxy groups, per anhydroglucose unit, may be designated as a degree of substitution of alkoxy groups, DS (alkoxy). For convenience in the definition of the DS, the term “hydroxy group substituted by alkyl groups” may be construed as including any type of substituted hydroxyl groups containing an alkyl or hydroxyalkyl group, including but not limited to alkylated hydroxy groups of hydroxyalkoxy substituents bound to the cellulose skeleton, as well as alkylated hydroxyl groups directly bound to carbon atoms of the cellulose skeleton. For example, the cellulose ether may have a DS (alkoxy) of about 1.0 to about 2.5, and in some embodiments, about 1.1 to about 2.4, and in some other embodiments, about 1.2 to about 2.2, and in some other embodiments, about 1.6 to about 2.05, and in some still other embodiments, about 1.7 to 2.05. When the cellulose ether has a DS (alkoxy) within these ranges, the cellulose ether may impart an appropriate viscosity even at a small amount. The DS (alkoxy) may be determined by Zeisel cleavage of the cellulose ether with hydrogen iodide and subsequent quantitative gas chromatography.

The binder may include at least about 80 wt % or greater, about 85 wt % or greater, about 90 wt % or greater, about 95 wt % or greater, or about 100 wt % of the cellulose ether based on a total weight of the binder. For example, the binder may substantially consist of the cellulose ether. In some embodiments, the binder may further include a binder that is commonly used in the art as long as the additional binder does not interfere with implementation of an appropriate concentration and viscosity of the thermoelectric material ink.

The solvent may function as a medium that allows uniform dispersion of the thermoelectric semiconductor particle and the binder in the thermoelectric material ink. The solvent may be an aqueous solvent or a non-aqueous solvent.

Non-limiting examples of the non-aqueous solvent may be water; C2-C6 monoalcohols (for example, ethanol, isopropanol, and the like); C2-C20 polyols, for example, C2-C10 or C2-C6 polyols (for example, glycerol, propylene glycol, butylene glycol, pentylene glycol, hexylene glycol, dipropylene glycol, and diethylene glycol); glycol ethers, for example, C3-C16 glycol ethers (for example, (C1-C4) alkyl ethers of mono-, di-, or tripropylene glycols, and (C1-C4) alkyl ethers of mono-, di-, or triethylene glycols); and a combination thereof.

The non-aqueous solvent may be an aprotic solvent, such as N-methyl-2-pyrrolidinone, propylene carbonate, ethylene carbonate, butylene carbonate, dimethyl carbonate, diethyl carbonate, gamma-butyrolactone, 1,2-dimethoxy ethane, tetrahydrofuran, 2-methyl tetrahydrofuran, dimethyl sulfoxide, 1,3-dioxolane, formamide, dimethylformamide, acetonitrile, nitromethane, methyl formate, methyl acetate, phosphoric acid triester, trimethoxymethane, a dioxolane derivative, sulfolane, methyl sulfolane, 1,3-dimethyl-2-imidazolidinone, a propylene carbonate derivative, a tetrahydrofuran derivative, ether, methyl pyrophosphate, ethyl propionate, and the like.

The solvent may be an aqueous solvent in view of the dispersion ability of the cellulose ether and good printability. For example, the solvent may be a mixed solvent of ethanol and water.

A weight ratio of the thermoelectric semiconductor particle to the solvent may be about 30:70 to about 90:10. For example, the weight ratio of the thermoelectric semiconductor particle to the solvent may be about 40:60 to about 80:20. For example, the weight ratio of the thermoelectric semiconductor particle to the solvent may be about 50:50 to about 70:30. When the weight ratio of the thermoelectric semiconductor particle to the solvent is within these ranges, uniform dispersion of the thermoelectric semiconductor particle and the binder and an appropriate viscosity for screen printing may be attained.

An amount of the binder including the cellulose ether may be in a range of about 0.01 parts to about 5 parts by weight with respect to 100 parts by weight of a total weight of the thermoelectric semiconductor particle and the solvent. For example, the amount of the binder including the cellulose ether may be about 0.1 parts to about 1 part by weight, and in some embodiments, about 0.3 parts to about 0.6 parts by weight, with respect to 100 parts by weight of the total weight of the thermoelectric semiconductor particle and the solvent. When the amount of the binder including the cellulose ether is within these ranges, an appropriate viscosity for screen printing may be provided with a small amount of the binder. For example, the binder may consist of the cellulose ether alone.

The thermoelectric material ink may have a viscosity of about 0.5 Pa·s to about 10.0 Pa·s. For example, the thermoelectric material ink may have a viscosity of about 1.0 Pa·s to about 5.0 Pa·s, and in some embodiments, about 3.0 Pa·s to about 4.0 Pa·s. When the thermoelectric material ink has a viscosity within these ranges, the thermoelectric material ink may be suitable for screen printing.

In accordance with an embodiment, there is provided a thermoelectric element obtained by printing (for example, by screen printing) and sintering the thermoelectric material ink according to any of the above-described embodiments, and then hot pressing a resulting product.

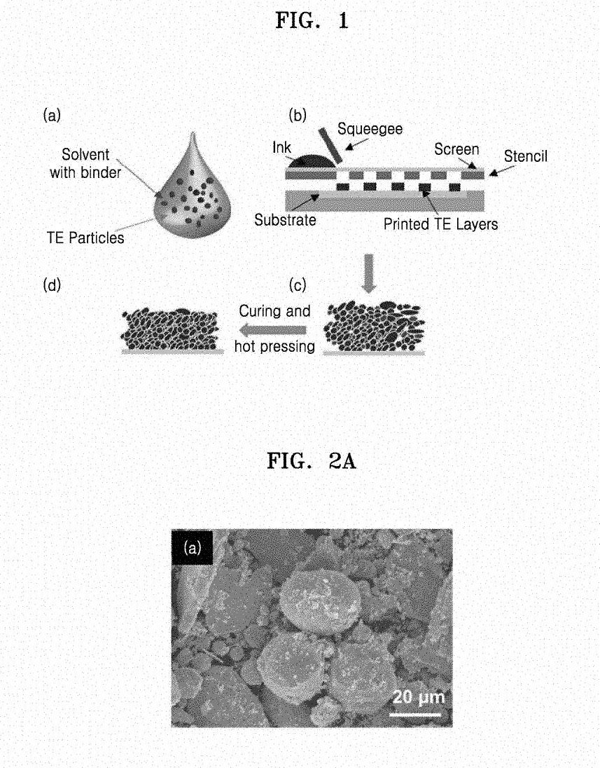

FIG. 1 is a schematic conceptual view illustrating a process of manufacturing a thermoelectric element according to an embodiment by using the thermoelectric material ink according to an embodiment.

In FIG. 1, (a) illustrates the thermoelectric material ink including a thermoelectric semiconductor particle, a binder, and a solvent as described in the above-embodiments. In the thermoelectric material ink, which is a uniform dispersion of the thermoelectric semiconductor particle and the binder in the solvent, the materials may be thoroughly mixed by gentle ball milling.

Once the thermoelectric material ink is prepared, the thermoelectric material ink may be applied to a pre-designed pattern laser cut stainless steel stencil with apertures to be deposited on the substrate (see (b) in FIG. 1). The stainless steel stencil may be designed using computer-aided design (CAD) software. In screen-printing, a force may be applied onto the thermoelectric material ink with a squeegee such that the thermoelectric material ink passes through the stencil or a mesh on the substrate where a printed thermoelectric layer is to be formed. The printed thermoelectric layer may be formed in various shapes according to patterns of the stencil. For example, the printed thermoelectric layer may be formed in a pillar form having a high aspect ratio on the substrate.

In FIG. 1, (c) is a partially enlarged view of the printed thermoelectric layer. After sintering and hot pressing of the printed thermoelectric layer, as illustrated in (d) of FIG. 1, the binder component may be pyrolyzed through combustion, and the thermoelectric semiconductor particles are densely compressed, so that the printed thermoelectric layer may have a reduced thickness and a remarkably increased electric conductivity.

The sintering may be performed in a temperature range of about 250° C. to about 350° C., so that the binder component may be pyrolyzed through combustion. The cellulose ether of the binder may be decomposed at a temperature lower than the temperature of common hot pressing. Accordingly, the sintering of the printed thermoelectric layer may be performed at a comparative low temperature within the above-ranges.

The hot pressing of the sintered printed thermoelectric layer may be performed at a high temperature of, for example, about 300° C. to about 800° C., and a high pressure of, for example, about 30 megaPascal (MPa) to about 300 MPa. Through the hot pressing under these conditions a thermoelectric element having a density of about 70% to about 100% of a theoretical density may be manufactured. The theoretical density may be calculated by dividing a molecular weight of the thermoelectric material by an atomic volume thereof, and the theoretical density may be evaluated according to a lattice constant. For example, the thermoelectric element may have a density of about 95% to about 100%, and accordingly have an increased electrical conductivity. The thermoelectric element after the hot pressing may have a thickness of about 10 μm to about 700 μm.

To prevent oxidation of the thermoelectric layer, the hot pressing may be performed under an inert gas atmosphere having an oxygen concentration of less than about 80 ppm.

In the thus formed thermoelectric element, the binder component is mostly removed through thermal decomposition during the sintering. Accordingly, the problem of an electrical conductivity reduction due to the residual binder may be solved, and the thermoelectric performance may also be improved due to a high density of the thermoelectric element implemented through the hot pressing.

In some embodiments, the thermoelectric element may include an embedded nanoscale defect resulting from the combustion of the binder. By rearrangement of the thermoelectric semiconductor particles during the combustion of the binder in the sintering process, a thin, long nanoscale defect of, for example, about hundreds of nanometers may be formed. The nanoscale defect may serve as an effective phonon scattering center to induce low lattice thermal conductivity in the printed thermoelectric element. Such nanoscale defects may occur, specifically when a thermoelectric material ink including n-type thermoelectric semiconductor particles is sintered.

The thermoelectric element may be a p-type thermoelectric element or an n-type thermoelectric element. The thermoelectric element may have a predetermined shape, for example, in a rectangular shape.

When connected to electrodes, the thermoelectric element may generate a cooling effect as a current is applied thereto, and may generate power using the temperature difference.

In accordance with an embodiment, a thermoelectric module includes a first electrode, a second electrode, and the thermoelectric element according to any of the above-described embodiments interposed between the first and second electrodes.

For example, the thermoelectric module may be implemented to generate a current through the thermoelectric element when there is a temperature difference between the first electrode and the second electrode. In the thermoelectric module, a first end of the thermoelectric element may be in contact with the first electrode, and a second end of the thermoelectric element may be in contact with the second electrode. When a temperature of the first electrode is increased to a temperature higher than a temperature of the second electrode, or when a temperature of the second electrode is decreased to a temperature lower than a temperature of the first electrode, a current flow from the first electrode to the second electrode through the thermoelectric element may occur. While the thermoelectric module is in operation, the first electrode and the second electrode may be electrically connected.

The thermoelectric module may further include a third electrode, wherein the thermoelectric module may further include a thermoelectric element disposed between the first electrode and the third electrode.

For example, the thermoelectric module may include a first electrode, a second electrode, a third electrode, a p-type thermoelectric element having a first end and a second end, and an n-type thermoelectric element having a first end and a second end, wherein the first end of the p-type thermoelectric element may be in contact with the first electrode, the second end of the p-type thermoelectric element may be in contact with the third electrode, the first end of the n-type thermoelectric element may be in contact with the first electrode, and the second end of the p-type thermoelectric element may be in contact with the second electrode. Thus, when a temperature of the first electrode is higher than those of the second electrode and the third electrode, a current that flows from the second electrode to the n-type thermoelectric element, to the first electrode through the n-type thermoelectric element, to the p-type thermoelectric element through the first electrode, and to the third electrode through the p-type thermoelectric element may be generated. The second electrode and the third electrode may be electrically connected while the thermoelectric module is in operation. At least one of the p-type thermoelectric element and the n-type thermoelectric element may include a thermoelectric material having a 3-dimensional (3D) structure.

The thermoelectric module may further include an insulating substrate on which at least one of the first electrode, the second electrode, and optionally the third electrode is disposed.

The insulating substrate may be a gallium arsenic (GaAs), sapphire, silicon, Pyrex, or a quartz substrate. The electrode may include aluminum, nickel, gold, titanium, or a combination thereof, and may also have various sizes. The electrode may be patterned by using various known patterning methods, such as a lift-off semiconductor process, a deposition method, or a photolithography method.

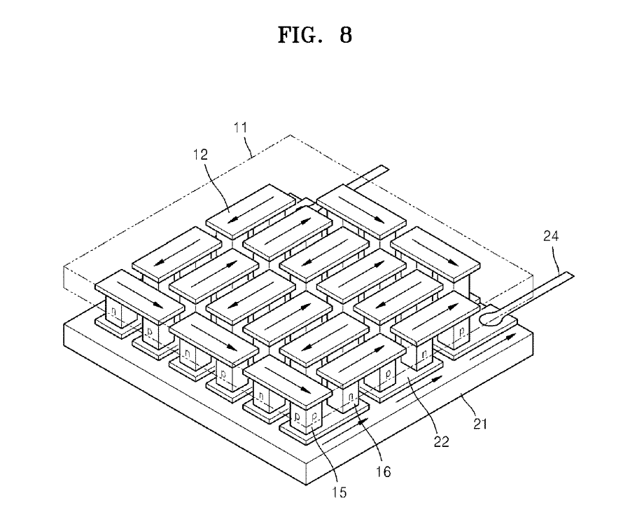

FIG. 8 illustrates an example of a thermoelectric module including the thermoelectric element according to any of the embodiments. Referring to FIG. 8, an upper electrode 12 and a lower electrode 22 may be patterned on an upper insulating substrate 11 and a lower insulating substrate 21, respectively. The upper electrode 12 and the lower electrode 22 may contact a p-type thermoelectric element 15 and an n-type thermoelectric element 16, respectively. The upper electrode 12 and the lower electrode 22 may be connected to the outside of the thermoelectric element by a lead electrode 24.

In the thermoelectric module, as illustrated in FIG. 8, the p-type thermoelectric element 15 and the n-type thermoelectric element 16 may be alternately aligned, and at least one of the p-type thermoelectric element 15 and the n-type thermoelectric element 16 may include the thermoelectric material including the 3D structure.

In the thermoelectric module, one of the first electrode and the second electrode may be electrically connected to a power source. A temperature difference between the first electrode and the second electrode may be 1 degree or greater, 5 degrees or greater, 50 degrees or greater, 100 degrees or greater, or 200 degrees or greater. A temperature of each of the first electrode and the second electrode may be any temperature as long as the temperature does not cause melting of any elements or current interference in the thermoelectric module.

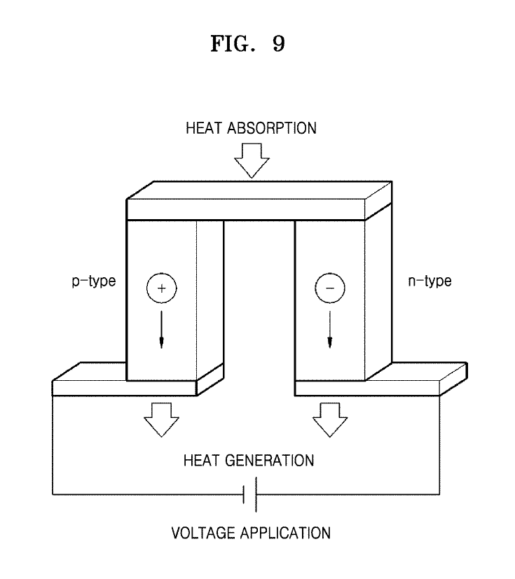

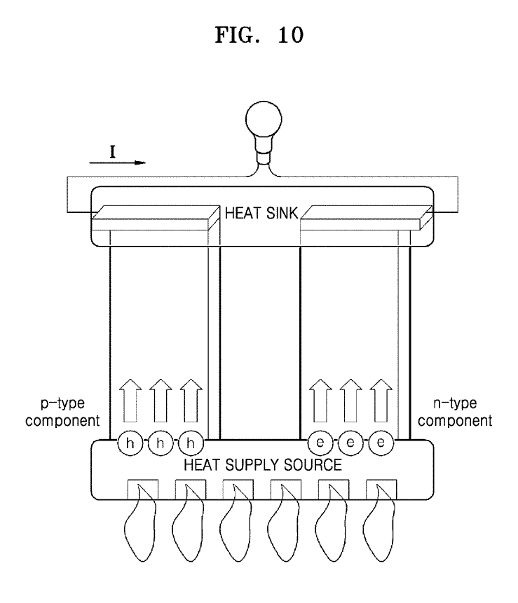

A thermoelectric module according to an embodiment may include, as illustrated in FIGS. 9 and 10, a first electrode, a second electrode, and the above-described thermoelectric element disposed between the first electrode and the second electrode. The thermoelectric module may further include an insulating substrate on which at least one of the first and second electrodes are disposed, as illustrated in FIG. 8. The insulating substrate may be any of the above-listed insulating substrates.

Referring to FIG. 9, in the thermoelectric module according to an embodiment, the first and second electrodes may be electrically connected to a power supply source. When an external direct current (DC) voltage is applied, holes of a p-type thermoelectric element and electrons of an n-type thermoelectric element may migrate, and thus heat may be generated and absorbed at both ends of the thermoelectric element.

Referring to FIG. 10, in a thermoelectric module according to an embodiment, at least one of the first and second electrodes may be exposed to a heat supply source. When heat is supplied from the heat supply source, electrons and holes may migrate to induce a current flow in the thermoelectric element, so that power is generated.

The thermoelectric module may be accommodated in a thermoelectric device such as a thermoelectric generator, a thermoelectric cooling system, and a thermoelectric sensor. However, embodiments are not limited thereto. The thermoelectric module may be accommodated and used in any device that directly converts heat to electricity or vice versa. The structure of the thermoelectric cooling system and a method of manufacturing the thermoelectric cooling system are well known in the art, and thus detailed descriptions thereof will be omitted herein.

In accordance with an embodiment, a flexible thermoelectric device includes: a flexible substrate including a fabric; and a thermoelectric layer that is printed on the flexible substrate, wherein an amount of carbon in the thermoelectric layer is about 3 atomic percent (atom %) or less.

The flexible thermoelectric device obtained by printing the thermoelectric layer on the flexible substrate including fabric may be used in the field of flexible, wearable applications.

The flexible substrate may include a fabric. The fabric may be, for example, fiber glass fabric.

The thermoelectric layer may be prepared by printing and sintering the thermoelectric material ink and then hot pressing a product from the sintering.

The thermoelectric device may further include an interface layer between the substrate and the thermoelectric layer. The interface layer may alleviate an effect of the roughness and porosity of the fabric substrate. By introducing the interlayer between the substrate including the fabric and the thermoelectric layer prior to the printing of the thermoelectric layer on the substrate, the rough, porous fabric may be softened to planarize a surface of the substrate and fill the pores of the substrate, and then the high-quality thermoelectric layer may then be formed thereon.

The interface layer may be a non-conductive layer, for example, including chitosan. The chitosan interface layer may remarkably reduce a surface roughness of the fabric to, for example, about 50 μm or less. Consequently, by formation of such a high-quality thermoelectric layer, electrical conductivity may be improved.

When the interface layer is introduced and the thickness of the thermoelectric layer is increased, the electrical conductivity may be further increased. When the thickness of the thermoelectric layer is increased, this may sacrifice flexibility of the thermoelectric layer. However, a thermoelectric layer printed in a small pillar form on the flexible substrate may still maintain flexibility of the thermoelectric device.

In accordance with an embodiment, a method of manufacturing a thermoelectric device includes: forming a thermoelectric layer on a flexible substrate including fabric by screen-printing the thermoelectric material ink according to any of the above-described embodiments; sintering the thermoelectric layer; and hot pressing the thermoelectric layer.

The thermoelectric semiconductor particle of the thermoelectric material ink may be obtained by spark erosion of a bulk thermoelectric semiconductor ingot. The spark erosion may effectively destruct the bulk thermoelectric semiconductor ingot into microparticles and nanoparticles. By using the thermoelectric semiconductor particles having such a bimodal particle size distribution, a high-density thermoelectric layer may be formed.

To alleviate an effect of the roughness and porosity of the fabric substrate, the method may further include, before the forming of the thermoelectric layer, forming an interface layer on the flexible substrate. Since the thermoelectric material ink according to the above-described embodiments contains a small amount of cellulose ether as a binder, an effect of the binder to, e.g., on, a Seebeck coefficient (S) of the thermoelectric material ink may be trivial. Accordingly, to increase a figure of merit (ZT) of the printed thermoelectric layer formed on the fabric substrate, before the forming of the thermoelectric layer on the fabric substrate, an interfacial layer may be formed to planarize a surface of the fabric substrate and fill the pores of the fabric substrate. Consequently, by formation of such a high-quality thermoelectric layer, electrical conductivity may be improved. For example, the interface layer may include chitosan.

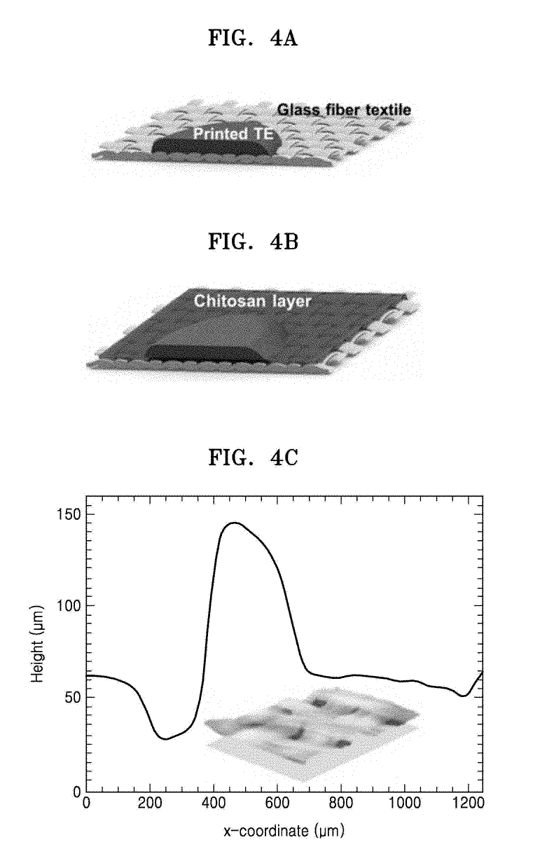

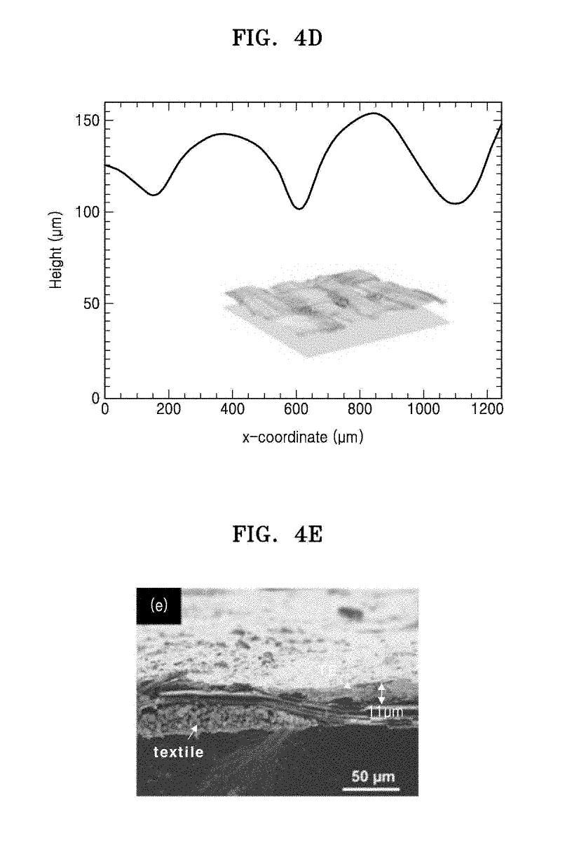

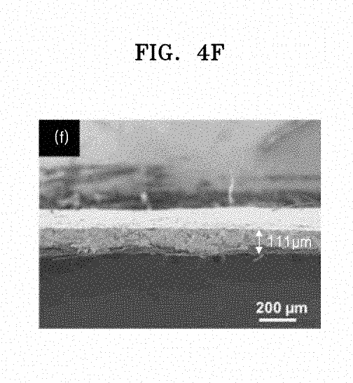

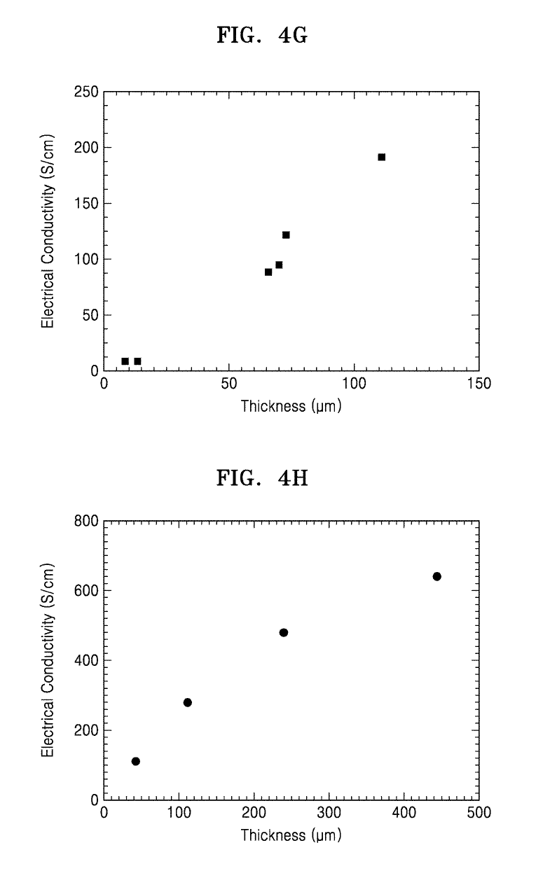

FIG. 4A illustrates an embodiment in which a thermoelectric layer is printed directly onto a fabric substrate, and FIG. 4B illustrates an embodiment in which a thermoelectric layer is printed after a chitosan layer is formed on a fabric substrate. The chitosan layer as an interface layer may planarize a surface of the fabric substrate and fill the pores of the fabric substrate, so that a high-quality thermoelectric layer may be formed on the interface layer.

The sintering and hot pressing of the thermoelectric layer, which are performed after the forming of the thermoelectric layer on the substrate by screen-printing the thermoelectric material ink, are the same as described above with reference to FIG. 1.

The thermoelectric material ink may be deposited on the substrate by applying the thermoelectric material ink to a pre-designed pattern laser cut stainless steel stencil with apertures. In screen-printing, a force may be applied onto the thermoelectric material ink with a squeegee such that the thermoelectric material ink passes through the stencil or a mesh on the substrate where a printed thermoelectric layer is to be formed. The thermoelectric layer may be formed in various shapes according to aperture patterns of the stencil. For example, the thermoelectric layer may be formed as an array of pillars having a high aspect ratio on the substrate.

The sintering of the printed thermoelectric layer may be performed in a temperature range of, about 250° C. to about 350° C. When the sintering is performed within this temperature range, the binder component may be pyrolyzed through combustion.

The hot pressing of the sintered thermoelectric layer may be performed at a high temperature of, for example, about 300° C. to about 800° C., and a high pressure of, for example, about 30 MPa to about 300 MPa. Through the hot pressing under these conditions a thermoelectric element having a density of about 70% to about 100% of a theoretical density may be manufactured.

The hot pressing may be performed under an inert gas atmosphere. For example, the hot pressing may be performed under an inert gas atmosphere having an oxygen concentration of less than about 80 ppm. This inert gas atmosphere condition may prevent oxidation of the thermoelectric layer.

One or more embodiments of the present disclosure will now be described in detail with reference to the following examples. However, these examples are only for illustrative purposes and are not intended to limit the scope of the one or more embodiments of the present disclosure.

### EXAMPLE 1

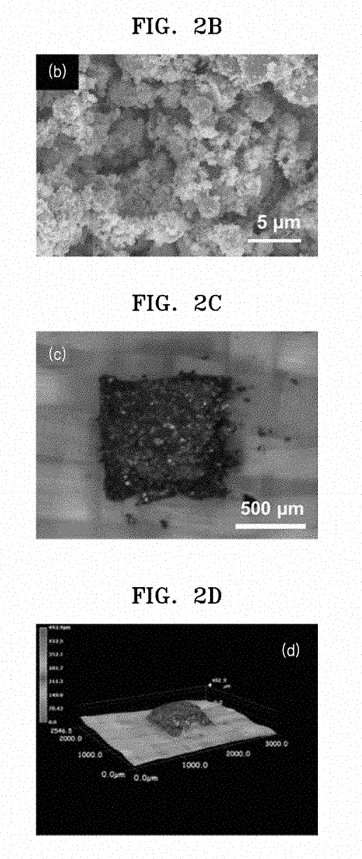

A spark erosion method was used to fabricate thermoelectric semiconductor particles (hereinafter, also referred to as “TE particles”). P-type and n-type bulk TE ingots with the compositions of Bi_{0.5}Sb_{1.5}Te₃ (hereinafter, referred to as “BST”) for p-type and Bi₂Te_{2.7}Se_{0.3} (hereinafter, referred to as “BTS”) for n-type were purchased from Thermonamic Inc. (China). The bulk ingots were destructed by spark erosion in a spark erosion cell filled with liquid nitrogen to obtain thermoelectric semiconductor particles. The obtained TE particles had a bimodal size distribution including microparticles greater than 10 μm (>10 μm) and nanoparticles smaller than 1 μm (<1 μm). Scanning electron microscope (SEM) images of the obtained microparticles and nanoparticles are shown in FIGS. 2A and 2B, respectively. The TE particles to be used for printing were passed through a 45 μm-mesh sieve.

The TE particles were mixed with a binder solution consisting of methyl cellulose as a binder (Methocel™ HG 90, available from DOW Wolff Cellulosics) in a mixed solvent of 60 wt % of ethanol and 40 wt % of water to obtain a TE ink. A weight ratio of the TE particles to the solvent was about 7:3, and about 2 parts by weight of the Methocel with respect to 100 parts by weight of the solvent was added. In consideration of the 7:3 weight ratio of the TE particles to the solvent, the amount of the Methocel was about 0.6 parts by weight with respect to 100 parts by weight of a final TE ink. The slurry was thoroughly mixed using gentle ball milling for a day, thereby preparing a TE ink having a viscosity of about 3.5 Pa·s.

Once the TE ink was prepared, the TE ink was applied to a pre-designed pattern laser cut stainless steel stencil with apertures to deposit the TE ink on a fiberglass fabric substrate (Fiberglass #00543, Fiber Glast Development Corporation), thereby forming a printed TE layer on the fiberglass fabric substrate. FIG. 2C is an optical microscope image of a printed TE layer on a fabric substrate before hot pressing, and FIG. 2D is an optical microscope (Keyence 3D optical microscope) image of the TE layer, showing that the printed TE layer on the fiberglass fabric substrate had an area of about 1 cm² and a thickness of about 500 μm.

The TE layer printed on the substrate was cured at about 250° C. to about 300° C. for about 30 minutes to solidify the sample and burn off the polymeric binder. Finally, the printed TE layer was hot pressed with a uniaxial pressure of about 90 MPa at about 450° C. for about 5 minutes. The hot pressing was carried out in an argon-filled glove box with an oxygen concentration less than 80 ppm. The TE layer after the screen printing and hot pressing had an area of about 1 cm² and a thickness of about 100 μm.

### EXAMPLE 2

A TE layer was formed in the same manner as in Example 1, except that the TE ink was printed after a chitosan layer was printed as an interface layer on the fabric substrate.

### EXAMPLE 3

A TE layer was formed on the fabric substrate in the same manner as in Example 1, except that the amount of the Methocel was varied to about 2.5 parts by weight with respect to 100 part by weight of the solvent.

### EXAMPLE 4

A TE layer was formed on the fabric substrate in the same manner as in Example 3, except that the weight ratio of the TE particles to the solvent was varied to about 5:5.

### EXAMPLE 5

A TE layer was formed on the fabric substrate in the same manner as in Example 4, except that the amount of the Methocel was varied to about 1.5 parts by weight with respect to 100 part by weight of the solvent.

### COMPARATIVE EXAMPLE 1

A TE layer was formed in the same manner as in Example 1, except that a TE ink consisting of about 70 wt % of TE particles and about 30 wt % of N-methyl-2-pyrrolidone (NMP) as a solvent was used without addition of a binder.

### COMPARATIVE EXAMPLE 2

A TE layer was formed in the same manner as in Example 1, except that a TE ink consisting of about 30 wt % of TE particles, about 50 wt % of NMP as a solvent, and about 20 wt % of polyvinylidene difluoride (PVDF) as a binder was used.

### COMPARATIVE EXAMPLE 3

A TE layer was formed in the same manner as in Example 1, except that a TE ink consisting of about 30 wt % of TE particles, about 50 wt % of NMP as a solvent, and about 20 wt % of Methocel as a binder was used.

### COMPARATIVE EXAMPLE 4

A TE layer was formed in the same manner as in Example 1, except that a TE ink consisting of about 71.8 wt % of TE particles, about 25.6 wt % of NMP as a solvent, and about 2.6 wt % of Methocel as a binder was used.

### COMPARATIVE EXAMPLE 5

A TE layer was formed in the same manner as in Example 1, except that a TE ink consisting of about 70 wt % of TE particles, about 25 wt % of NMP as a solvent, and about 5 wt % of Methocel as a binder was used.

### EVALUATION EXAMPLE 1

### Printability Evaluation

To evaluate printability of each of the TE inks prepared in Examples 1 to 5 and Comparative Examples 1 to 5, uniformities and shapes of the printed PE layers were investigated.

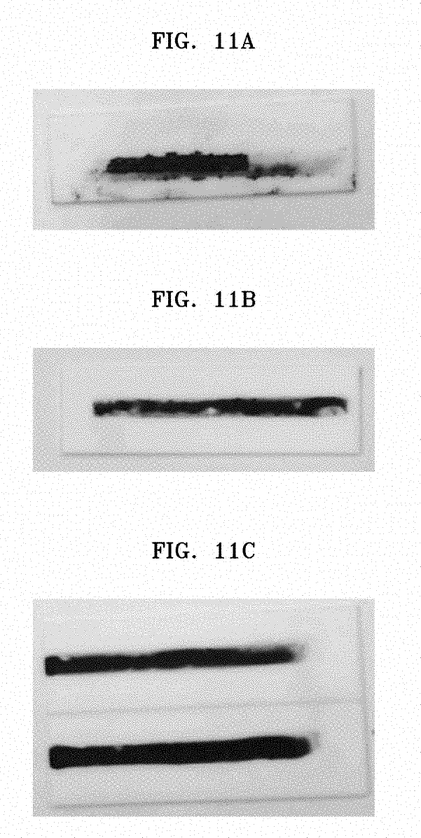

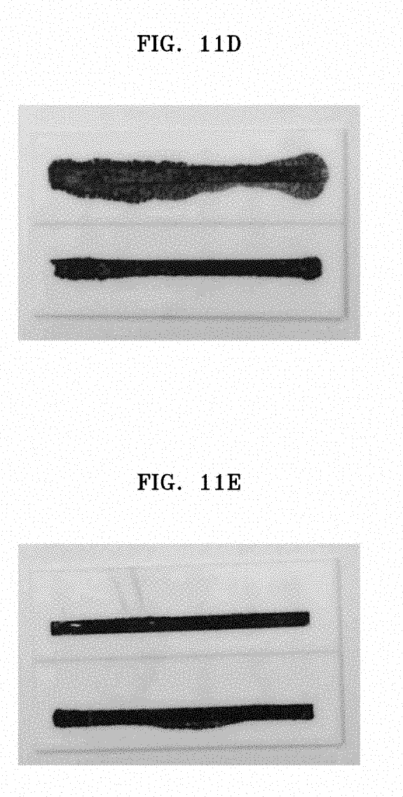

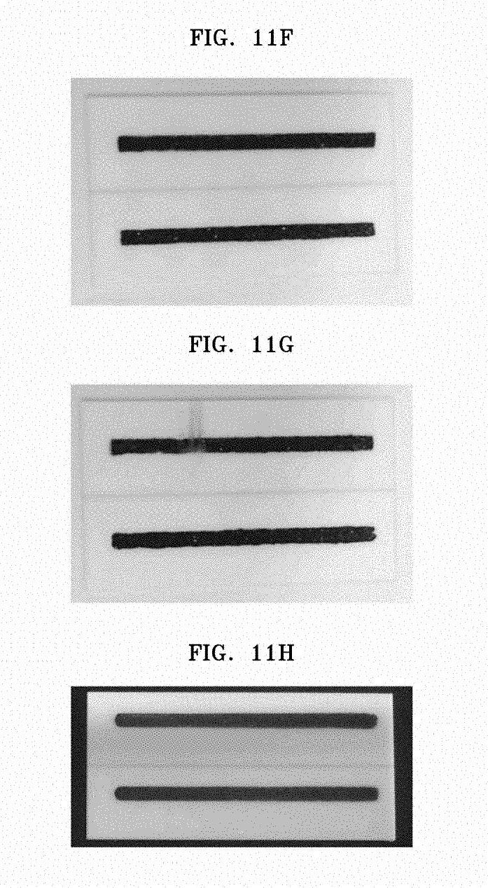

The printing results with the TE inks of Comparative Examples 1-5 and Example 3-5 are shown in FIGS. 11A to 11H, respectively.

Referring to FIGS. 1A to 11H, the TE ink of Comparative Example 1 prepared using a high content of TE particles without use of a binder was found to have very poor printability because the TE ink was almost solid. The TE ink of Comparative Example 2 prepared using the PVDF binder, which is commonly used in printing battery applications, and the increased amounts of the solvent and the binder to enable screen printing was found to exhibit printability but poor uniformity of the printed TE layer.

When the PVDF binder was partially or completely substituted with the Methocel and the amount of the Methocel was greater than 5 parts by weight with respect to 100 parts by weight of a total weight of the TE particles and the solvent, the printing uniformity was not good. However, when the amount of the Methocel was about 5 parts by weight or less with respect to 100 parts by weight of the total weight of the TE particles and the solvent, printability, and uniformity of the TE layer were both good.

The TE layers of Examples 1 and 2 were found to be the best in printability. Accordingly, thermoelectric performances of the TE layers of Examples 1 and 2 were evaluated as follows.

### EVALUATION EXAMPLE 2

### Thermoelectric Performance Measurement

Energy conversion efficiency of thermoelectric materials is represented by a dimensionless figure of merit (ZT) as defined by Equation 1.

$$ZT = \frac{{S}^{2} σ T}{κ} \qquad Equation 1$$

In Equation 1, ZT is a figure of merit, S is a Seebeck coefficient, σ is an electrical conductivity, T is an absolute temperature, and κ is a thermal conductivity

To evaluate the thermoelectric performance of the TE layers of Examples 1 and 2, a dimensionless figure of merit (ZT), including a Seebeck coefficient (S), an electrical conductivity (σ), and a thermal conductivity (κ), were evaluated at room temperature.

The Seebeck coefficient and the electrical conductivity were measured by the van der Pauw method using a ZEM-3 (ULVAC-RIKO, Inc.). The thermal conductivity and lattice thermal conductivity were evaluated by measuring thermal diffusivity by using the Angstrom method. The figure of merit (ZT) was calculated using these measurement values.

### (1) Seebeck Coefficient

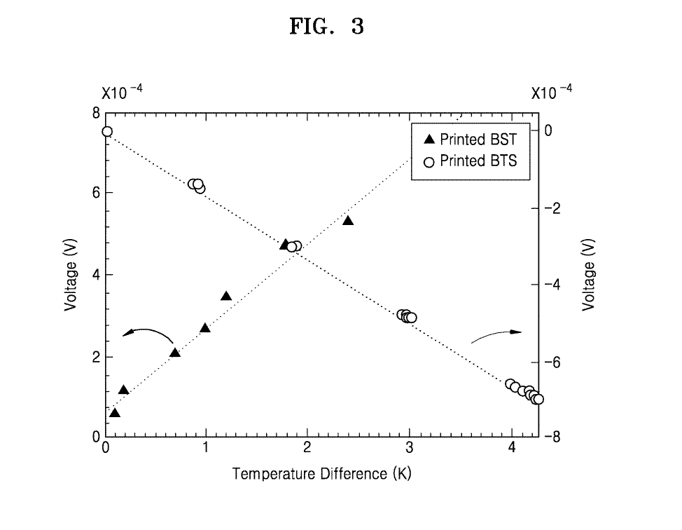

The in-plane Seebeck coefficient (S) measurement results of the TE layer of Example 2 are shown in FIG. 3, wherein the S is determined by the linear slope in the plot of thermovoltage as a function of temperature difference (i.e., S=−dV/dT). Referring to FIG. 3, the S was found to be 209 microVolts per degree Kelvin (μV/K) and −165 μV/K in n-type BST and n-type BTS materials, respectively. The printed TE layer was found to have similar S compared to that of TE particles. The TE particles dispersed in an organic solvent were drop-casted on a glass substrate and dried, and then the S of the TE particles was measured. This shows that the addition of the Methocel binder has minimal influence on the S value.

### (2) Electrical Conductivity

To compare the electrical conductivity measurement results when the interface layer was formed or not, the roughness of the fabric substrate surface used in each of Examples 1 and 2 was observed using a Keyence optical surface profiler. The results are shown in FIGS. 4C and 4D, respectively. The electrical conductivity measurement results of the TE layers formed in Examples 1 and 2 are shown in FIGS. 4H and 4I, respectively.

Referring to FIG. 4C, the bare fabric substrate surface without chitosan layer thereon was found to have a large roughness of about 100 μm or greater. Referring to FIG. 4G, the p-type BST layer printed on the bare fabric substrate was found to have an electrical conductivity (a) of less than 200 S/cm. The electrical conductivity (σ) increased with the thickness of the printed and hot-pressed TE layer. The electrical conductivity (σ) was increased from about 8.5 S/cm to 190 S/cm when the thickness of the TE layer was increased from about 9 μm to about 111 μm (see FIGS. 4E and 4F), suggesting the detrimental effect of the substrate.

On the other hand, as shown in FIG. 4D, the presence of the chitosan layer on the fabric substrate greatly reduced the surface roughness of the fabric to within 50 μm. Consequently, the electrical conductivity was largely improved as shown in FIG. 4H. At the same thickness of the TE layer of ˜110 μm, forming the chitosan layer increased the electrical conductivity from about 190 S/cm (see FIG. 4G) to about 278 S/cm (see FIG. 4H).

A similar electrical conductivity measurement was performed on n-type BTS by introducing the chitosan layer and varying the printed TE layer thickness. As a result, the electrical conductivity (σ) was improved up to about 639 S/cm and about 763 S/cm for p-type BST and n-type BTS on samples having chitosan and TE layers having a thickness of several to hundreds of micrometers (um).

### (3) Thermal Conductivity

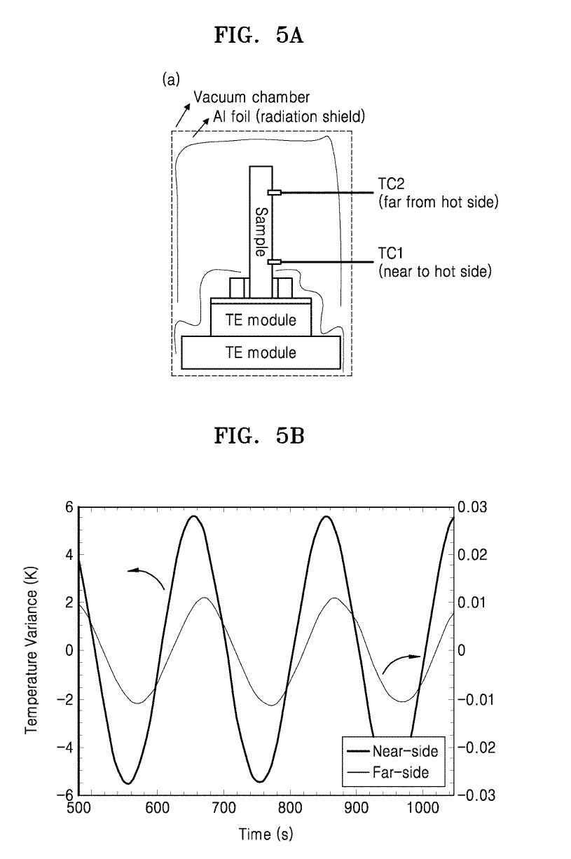

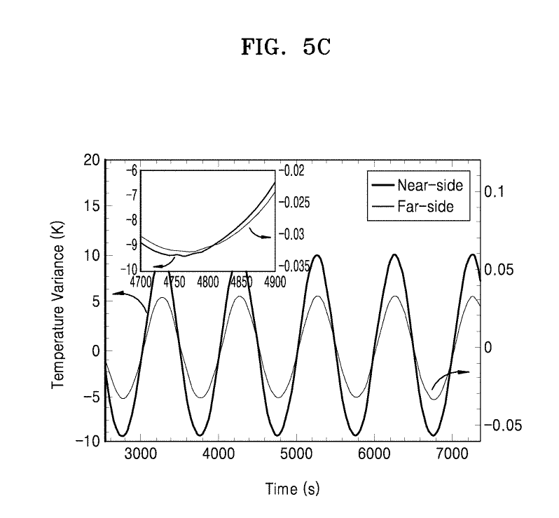

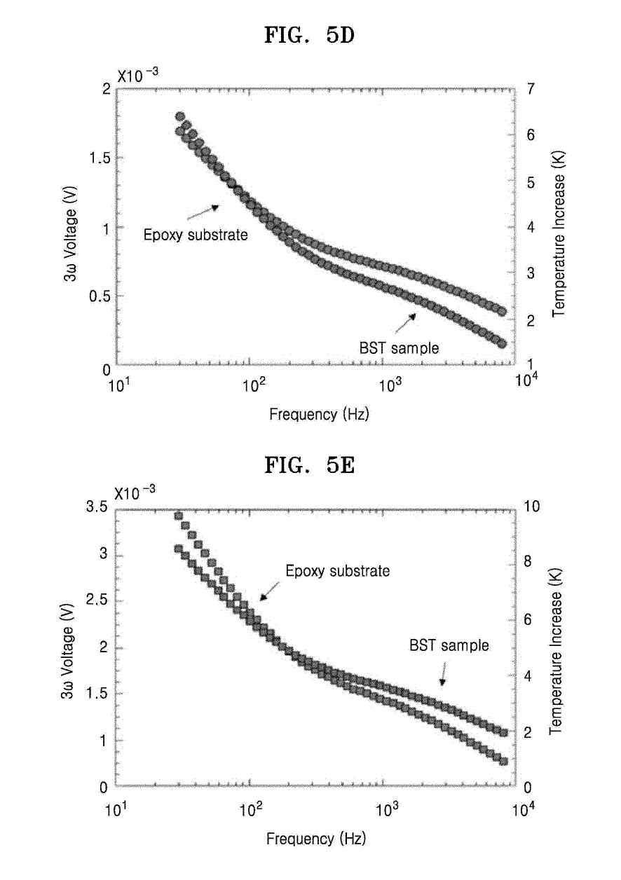

The Angstrom method was used to measure the in-plane thermal conductivity (κ|) of the printed TE layer of Example 1. In this method, one end of the sample was heated using a sinusoidal heat source, and the temperature waves were measured at two different locations of the sample, as shown in FIG. 5A. The setup was calibrated with measurements on borosilicate and polyethylene, which have well-known thermal conductivity values. The temperature wave measurement results of p-type BST and n-type BTS TE layers are shown in FIGS. 5B and 5C, respectively. The measured κ_{|} was found to be 1.29 and 0.77 W/m-K for the thickest (600-800 μm) p-type BST and n-type BTS layers.

To assess the anisotropy of the thermal conductivity, the cross-plane thermal conductivity (κ_{⊥}) for p-type and n-type TE layers was measured using the 3 ω-technique. For the p-type and n-type TE layers, plots of voltage and temperature as a function of heating frequency are shown in FIGS. 5D and 5E, respectively. Using the slope method, e.g., by calculating the slope of the plot, the cross-plane thermal conductivity (κ_{⊥}) was found to be about 1.06 W/m-K and about 0.83 W/m-K at 300 K for the p-type and n-type TE layers, respectively. The in-plane and cross-plane thermal conductivity results suggest that the printed TE layers were essentially isotropic after the uniaxial hot pressing process.

With the measured in-plane electrical conductivity and thermal conductivity, it is possible to estimate the lattice thermal conductivity: κ_{L}=κ−LσT, where L is the Lorenz number, and is taken to be about 1.67×10⁻⁸ Watts-Ohms-Kelvin⁻² (WΩK⁻²) and about 1.74×10⁻⁸ WΩK⁻² for p-type BST and n-type BTS, respectively, where the L was corrected with S; σ is the electrical conductivity; and T is the temperature. The calculated lattice thermal conductivity (κ_{L}) was about 0.97 Watts per meter-Kelvin (W/m-K) and about 0.37 W/m-K for the p-type and n-type layers, respectively.

The lattice thermal conductivity (κ_{L}) for p-type BST was almost identical to that of the starting bulk material value (calculated to be 1.04 W/m-K). However, the lattice thermal conductivity (κ_{L}) for n-type BST was significantly lower than the starting bulk value (1.23 W/m-K). This difference in lattice thermal conductivity (κ_{L}) between the p- and n-type printed layers is likely originated from the microstructures, which will be described below.

### (4) Investigation of Microstructure

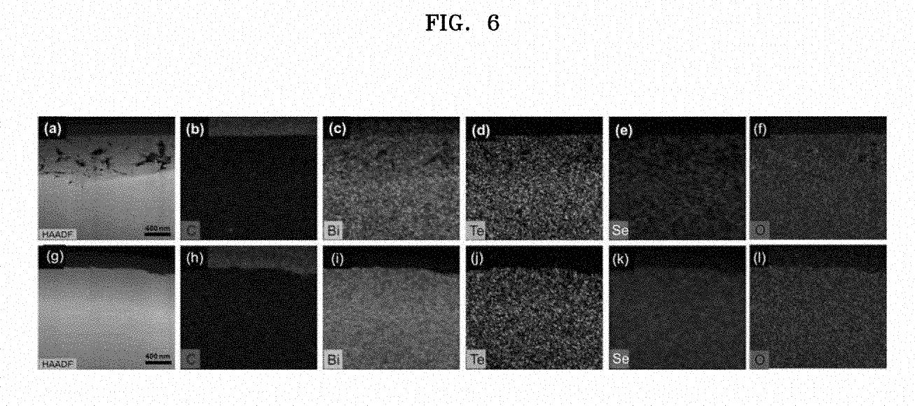

In order to investigate the relations between the measured thermoelectric properties and microstructures, high resolution-transmission electron microscopy (HR-TEM) was employed. The cross-sectional HR-TEM Energy-dispersive X-ray spectroscopy (EDS) element mapping images of the n-type TE layer of Example 1 are shown in FIG. 6. In FIG. 6, (a) to (f) are TEM EDS images of the p-type BST, and (g) to (l) are TEM EDS images of the n-type BTS. FIG. 6 shows the carbon element distributed in the p-type and n-type TE layers

In order to compare the amounts of carbon in the sintered samples, EDS quantifications were carried out.

TABLE 1

| EDS quantification | | | | | | | |
|---|---|---|---|---|---|---|---|
| (atom %) | | Bi | Sb | Se | Te | C | O |
| p-type | Without | 14.44 | 28.57 | — | 51.43 | 2.11 | 3.48 |
| BST | Methocel | | | | | | |
| | With Methocel | 13.06 | 29.94 | — | 52.14 | 1.98 | 2.97 |
| n-type | Without | 43.56 | — | 3.85 | 46.50 | 3.73 | 1.29 |
| BTS | Methocel | | | | | | |
| | With Methocel | 46.64 | — | 2.58 | 47.21 | 2.54 | 1.05 |

Referring to Table 1, the atomic percent of carbon in the samples with Methocel is similar to that in the samples without Methocel, revealing that the binders in the p-type and n-type were effectively removed without oxidizing the TE components and degrading the electrical conductivity. Therefore, the carbon elements observed with the binder in FIG. 6 are attributed to the hydrocarbon contamination in the sample surfaces.

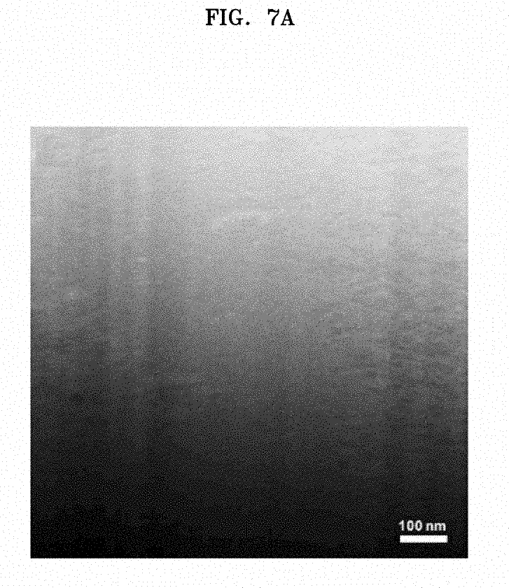

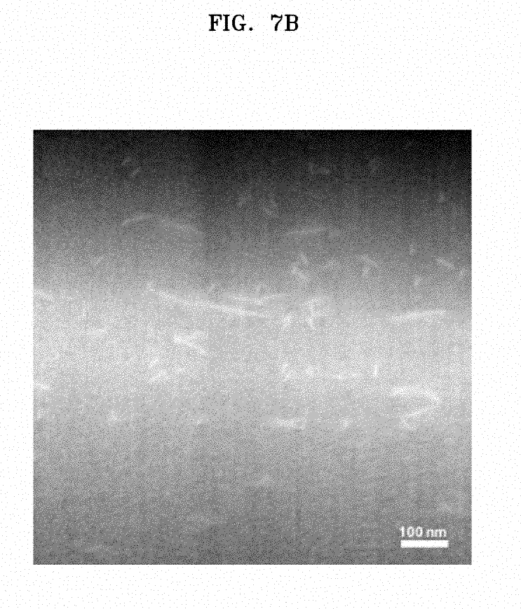

For the p-type printed sample, there was found no clear nanoscale feature in the high-angle annular dark-field (HAADF) image in FIG. 7A, similar to the case of hot-pressed p-type BST without Methocel. However, for the n-type sample, the defects with a length scale of a few hundred nanometers were clearly observed in the printed sample with Methocel after hot pressing as shown in the HAADF image in FIG. 7B. Considering that these defects were not found in the samples without Methocel, it seems that these thin and long defects were generated by the rearrangement of n-type TE particles while the binders were burning out in the sintering process, which could have facilitated the formation of the embedded defects. The nanoscale defects can effectively scatter phonons, in addition to causing boundary scattering, due to the formation of spark-eroded particles, leading to lower lattice thermal conductivity in the printed n-type layers without significantly affecting charge transport. Thus, the thermal conductivity of the printed n-type samples is lowered compared to that of the bulk.

### (5) Figure of Merit (ZT Value)

As a result of calculating the ZT values for the p-type and n-type printed TE layers with the measured in-plane S, σ, and κ, the ZT values were found to be 0.68 and 0.81 for the p-type and n-type printed layers, respectively. These values are among the highest for the printed TE samples.

As described above, according to the one or more embodiments, a printed thermoelectric element having high thermoelectric performance may be manufactured using the thermoelectric material ink according to the one or more embodiments

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims.

What is claimed is:

1. A thermoelectric material ink comprising:
a thermoelectric semiconductor particle;
a binder comprising a cellulose ether; and
a solvent,
wherein the thermoelectric material ink is screen-printable.

2. The thermoelectric material ink of claim 1, wherein the thermoelectric semiconductor particle has a bimodal particle size distribution including microparticles and nanoparticles.

3. The thermoelectric material ink of claim 1, wherein the microparticles have an average particle diameter of about 1 micrometer to about 100 micrometers, and the nanoparticles have an average particle diameter of about 10 nanometers to about 500 nanometers.

4. The thermoelectric material ink of claim 1, wherein the cellulose ether comprises an alkyl cellulose, a hydroxyalkyl cellulose, a hydroxyalkyl alkyl cellulose, or a combination thereof.

5. The thermoelectric material ink of claim 4, wherein the alkyl cellulose comprises methyl cellulose, ethyl cellulose, propyl cellulose, or a combination thereof,
the hydroxyalkyl cellulose comprises hydroxyethyl cellulose, hydroxypropyl cellulose, hydroxybutyl cellulose, or a combination thereof, and
the hydroxyalkyl alkyl cellulose comprises hydroxyethyl methyl cellulose, hydroxymethyl ethyl cellulose, hydroxyethyl ethyl cellulose, hydroxypropyl methyl cellulose, hydroxypropyl ethyl cellulose, hydroxybutyl methyl cellulose, hydroxybutyl ethyl cellulose, hydroxyethyl hydroxypropyl methyl cellulose, or a combination thereof.

6. The thermoelectric material ink of claim 1, wherein a weight ratio of the thermoelectric semiconductor particle to the solvent is in a range of about 30:70 to about 90:10.

7. The thermoelectric material ink of claim 1, wherein an amount of the binder comprising the cellulose ether is in a range of about 0.01 parts to about 5 parts by weight with respect to 100 parts by weight of a total weight of the thermoelectric semiconductor particle and the solvent.

8. The thermoelectric material ink of claim 1, wherein the thermoelectric semiconductor particle comprises at least one of a Bi—Te compound, a Co—Sb compound, a Pb—Te compound, a Ge—Tb compound, a Si—Ge compound, a Sb—Te compound, a Sm—Co compound, a transition metal silicide material, or a combination thereof.

9. The thermoelectric material ink of claim 1, wherein the thermoelectric material ink has a viscosity of about 0.5 Pa·s to about 10.0 Pa·s.

10. A thermoelectric element obtained by printing and sintering the thermoelectric material ink according to claim 1 and then hot pressing a resulting product, wherein an amount of carbon in the thermoelectric element is about 3 atom % or less.

11. The thermoelectric element of claim 10, wherein the thermoelectric element further comprises a nanoscale defect embedded in the thermoelectric element.

12. A thermoelectric module comprising:
a first electrode;
a second electrode; and
the thermoelectric element according to claim 11 located between the first electrode and the second electrode.

13. A flexible thermoelectric device comprising:
a flexible substrate comprising a fabric; and
a thermoelectric layer that is printed on the flexible substrate, wherein an amount of carbon in the thermoelectric layer is about 3 atom % or less.

14. The thermoelectric device of claim 13, wherein the thermoelectric layer comprises a nanoscale defect embedded in the thermoelectric layer.

15. The thermoelectric device of claim 13, further comprising an interface layer between the substrate and the thermoelectric layer.

16. The thermoelectric device of claim 15, wherein the interface layer comprises chitosan.

17. A method of manufacturing a flexible thermoelectric device, the method comprising:
forming a thermoelectric layer on a flexible substrate comprising a fabric by screen-printing the thermoelectric material ink according to claim 1 onto the flexible substrate;
sintering the thermoelectric layer; and
hot pressing the thermoelectric layer.

18. The method of claim 17, wherein the thermoelectric layer is formed from a thermoelectric semiconductor particle obtained by spark erosion of a bulk thermoelectric semiconductor ingot.

19. The method of claim 17, further comprising, before the forming of the thermoelectric layer, forming an interface layer on the flexible substrate, the interface layer comprising chitosan.

20. The method of claim 17, wherein the hot pressing is performed in an inert gas atmosphere.
